(19) United States
(12) Patent Application Publication
(10) Pub. No.: US 2014/0334112 A1
(43) Pub. Date: Nov. 13, 2014

(54) MOTHERBOARD WITH CONNECTOR COMPATIBLE WITH DIFFERENT INTERFACE STANDARDS

(71) Applicants: HONG FU JIN PRECISION INDUSTRY (ShenZhen) CO., LTD., Shenzhen (CN); HON HAI PRECISION INDUSTRY CO., LTD., New Taipei (TW)

(72) Inventors: BO TIAN, Shenzhen (CN); KANG WU, Shenzhen (CN)

(73) Assignees: HONG FU JIN PRECISION INDUSTRY (ShenZhen) CO., LTD., Shenzhen (CN); HON HAI PRECISION INDUSTRY CO., LTD., New Taipei (TW)

(21) Appl. No.: 14/271,524

(22) Filed: May 7, 2014

(30) Foreign Application Priority Data
May 9, 2013 (CN) 2013101678794

(51) Int. Cl. G06F 13/40; H05K 1/18

(52) U.S. Cl. CPC G06F 13/4022; H05K 1/18
USPC 361/729

(57) ABSTRACT

A motherboard includes a first connector, a first signal module, a second signal module, a control module, a power module, and a switch module. The first connector is used to connect external devices to the motherboard. The first signal module and the second signal module are compatible for external devices under different interface standards. The control module outputs different control signals to control the switch module corresponding to the external device connected to the motherboard. The switch module connects the first signal module or the second signal module to the first connector corresponding to the control signals received from the control module.

### FIELD

The present disclosure relates to a motherboard.

### BACKGROUND

Typically, a motherboard connector can only communicate with an external device sharing a specific standard.

### BRIEF DESCRIPTION OF THE DRAWINGS

Many aspects of the present disclosure can be better understood with reference to the following drawing(s). The components in the drawing(s) are not necessarily drawn to scale, the emphasis instead being placed upon clearly illustrating the principles of the present disclosure. Moreover, in the drawing(s), like reference numerals designate corresponding parts throughout the several views.

FIG. 1 is a block diagram of an embodiment of a motherboard of the present disclosure.

FIG. 2 is a circuit diagram of an embodiment of a motherboard of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.” The reference “a plurality of” means “at least two.”

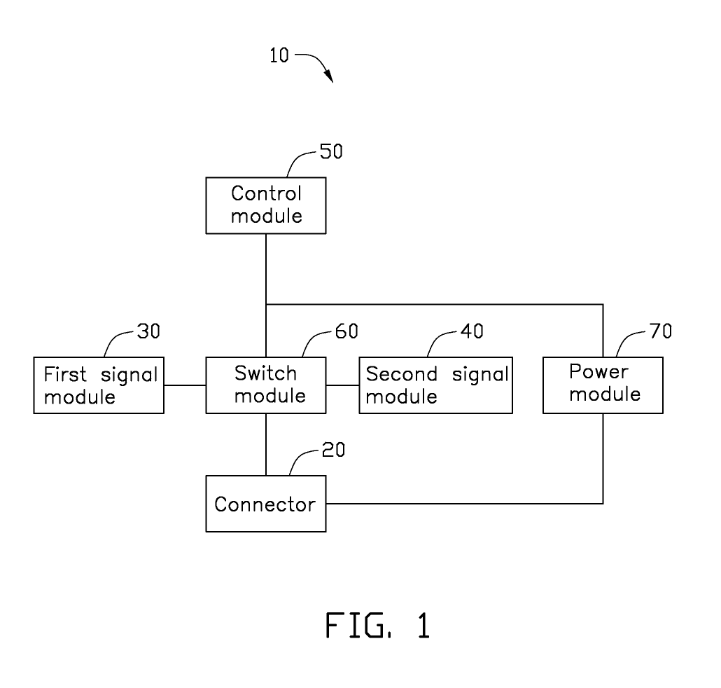

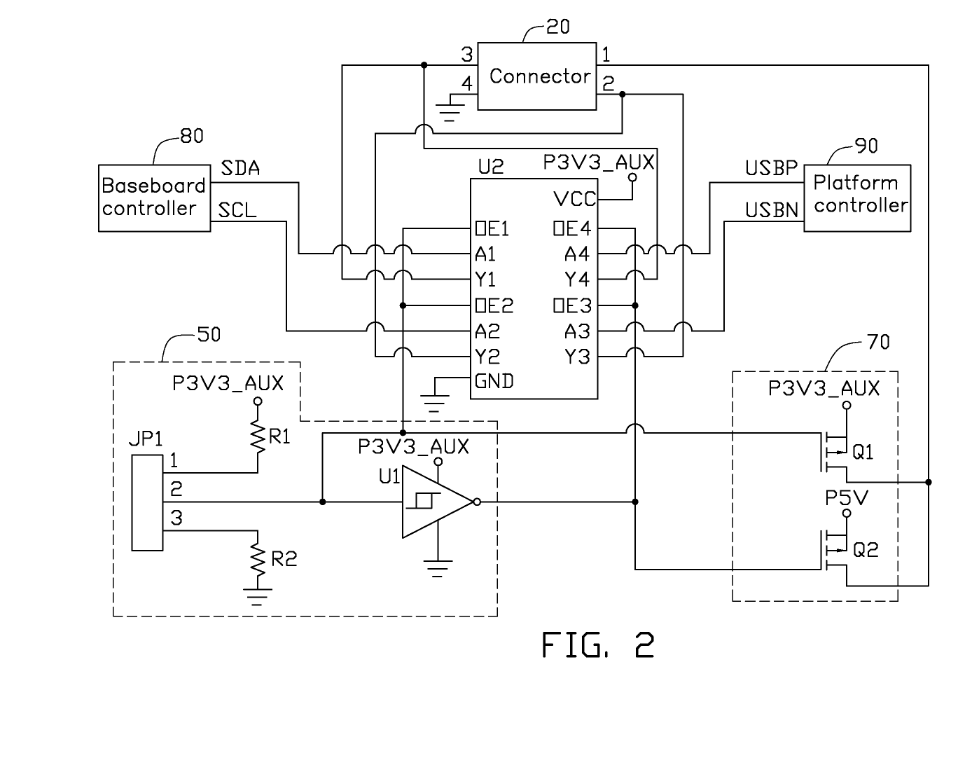

FIG. 1 and FIG. 2 illustrate an embodiment of a motherboard 10 of the present disclosure.

The motherboard 10 comprises a connector 20, a first signal module 30, a second signal module 40, a control module 50, a switch module 60, and a power module 70. The connector 20, the first signal module 30, the second signal module 40, and the control module 50 are connected to the switch module 60. The power module 70 is coupled between the control module 50 and the connector 20.

The control module 50 comprises a connector JP1, a power input terminal P3V3_AUX, a resistor R1, a resistor R2, and an inverter U1. A pin 1 of the connector JP1 is coupled to the power input terminal P3V3_AUX through the resistor R1. A pin 2 of the connector JP1 is connected to an input terminal of the inverter U1. The pin 2 of the connector JP1 is connected to the switch module 60. The pin 2 of the connector JP1 is also connected to the power module 70. A pin 3 of the connector JP1 is coupled through the resistor R2 to ground. A power terminal of the inverter U1 is connected to the power input terminal P3V3_AUX. A ground terminal of the inverter U1 is grounded. An output terminal of the inverter U1 is coupled to the power module 70 and the switch module 60.

The switch module 60 comprises a chip U2. A pin OE1 of the chip U2 and a pin OE2 of the chip U2 are connected to the pin 2 of the connector JP1. A pin OE3 of the chip U2 and a pin OE4 of the chip U2 are connected to the output terminal of the inverter U1. A pin A1 of the chip U2 and a pin A2 of the chip U2 are connected to the second signal module 40. A pin A3 of the chip U2 and a pin A4 of the chip U2 are connected to the first signal module 30.

The first signal module 30 comprises a platform controller 90. A pin USBP of the platform controller 90 is connected to the pin A3 of the chip U2. A pin USBN of the platform controller 90 is connected to the pin A4 of the chip U2.

The second signal module 40 comprises a baseboard controller 80. A pin SDA of the baseboard controller 80 is connected to the pin A1 of the chip U2. A pin SCL of the baseboard controller 80 is connected to the pin A2 of the chip U2.

The power module 70 comprises electronic switches Q1 and Q2. A first terminal of the electronic switch Q1 is connected to the pin 2 of the connector JP1. A second terminal of the electronic switch Q1 is connected to the power input terminal P3V3_AUX. A third terminal of the electronic switch is connected to the pin 1 of the connector 20. A first terminal of the electronic switch Q2 is connected to the output terminal of the inverter U1. A second terminal of the electronic switch Q2 is connected to a power input terminal P5V. A third terminal of the electronic switch Q2 is connected to the pin 1 of the connector 20.

The pin 2 of the connector JP1 is connected to the pin 3 of the connector JP1 with a jumper when the connector 20 is connected to a first external device, which uses a system management bus to communicate with the baseboard controller 80. The pin 2 of the connector JP1 is at a low voltage level. The inverter U1 outputs a high level signal. The electronic switch Q2 is turned off when the first terminal of the electronic switch Q2 receives a high level signal. The electronic switch Q1 is turned on when the first terminal of the electronic switch Q1 receives a low level signal. The power input terminal P3V3_AUX supplies power to the pin 1 of the connector 20. The pin A1 of the chip U2 is connected to the pin Y1 of the chip U2 when the pin OE1 of the chip U2 is at a low level. The pin A2 of the chip U2 is connected to the pin Y2 of the chip U2 when the pin OE2 is at a low level. The pin A3 of the chip U2 is disconnected from the pin Y3 of the chip U2 when the pin OE3 is at a high level. The pin A4 of the chip U2 is disconnected from the pin Y4 of the chip U2 when the pin OE4 is at a high level. The connector 20 is connected to the baseboard controller 80. The first external device communicates with the baseboard controller 80 through the connector 20.

The pin 1 of the connector JP1 is connected to the pin 2 of the connector JP1 with the jumper when the connector 20 is connected to a second external device, which communicates with the platform controller 90. The pin 2 of the connector JP1 is at a high level. The inverter U1 outputs a low level signal. The electronic switch Q1 is turned off The electronic switch Q2 is turned on. The power input terminal P5V supplies power to the pin 1 of the connector 20. The pin A1 is disconnected from the pin Y1 when the pin OE1 is at a high level. The pin A2 is disconnected from the pin Y2 when the pin OE2 is at a high level. The pin A3 is connected to the pin Y3 when the pin OE3 is at a low level. The pin A4 is connected to the pin Y4 when the pin OE3 is at a low level. The second external device communicates with the platform controller 90 through the connector 20.

In the embodiment, the electronic switches Q1 and Q2 are p-channel field effect transistors. The inverter U1 is a single trigger Schmitt inverter.

While the disclosure has been described by way of example and in terms of preferred embodiment, it is to be understood that the disclosure is not limited thereto. To the contrary, it is intended to cover various modifications and similar arrangements as would be apparent to those skilled in the art. Therefore, the range of the appended claims should be accorded the broadest interpretation so as to encompass all such modifications and similar arrangements.

What is claimed is:

1. A motherboard, comprising:
a first connector selectively connected to a first external device and a second external device;
a first signal module to communicate with the first external device;
a second signal module to communicate with the second external device;
a control module, wherein the control module outputs a first signal when the first connector is connected to the first external device, the control module outputs a second signal when the first connector is connected to the second external device;
a switch module connected to the first connector, the first signal module, the second signal module, and the control module, wherein the switch module connects the first signal module to the first connector and disconnects the second signal module from the first connector when the switch module receives the first signal from the control module, and the switch module connects the second signal module to the first connector and disconnects the first signal module from the first connector when the switch module receives the second signal from the control module.

2. The motherboard of claim 1, wherein the control module comprises a second connector, a first power input terminal, a first resistor, a second resistor, and an inverter, a first pin of the second connector is connected to the first power input terminal through the first resistor, a second pin of the second connector is connected to an input terminal of the inverter, the switch module, and the power module, a third pin of the second connector is grounded through the second resistor, a power terminal of the inverter is connected to the first power input terminal, a ground terminal of the inverter is grounded, and an output terminal of the inverter is connected to the switch module and the power module.

3. The motherboard of claim 2, wherein the switch module further comprises a chip, a first control pin and a second control pin of the chip are connected to the second pin of the second connector, a third control pin and a fourth control pin of the chip are connected to the output terminal of the inverter, the first signal module comprises a baseboard controller, a first pin of the baseboard controller is connected to a first input pin of the chip, a second pin of the baseboard controller is connected to a second input pin of the chip, the second signal module comprises a platform controller, a first pin of the platform controller is connected to a third input pin of the chip, a second pin of the platform controller is connected to a fourth input pin of the chip, a second output pin and a third output pin of the chip are connected to a second pin of the first connector, the first output pin is connected to a third pin of the first connector, and a fourth output pin is connected to a third pin of the first connector, the first input pin of the chip is connected to the first output pin of the chip when the first control pin of the chip is at a low level, the first input pin of the chip is disconnected from the first output pin of the chip when the first control pin of the chip is at a high level, the second input pin of the chip is connected to the second output pin of the chip when the second control pin of the chip is at a low level, the second input pin of the chip is disconnected from the second output pin of the chip when the second control pin of the chip is at a high level, the third input pin of the chip is connected to the third output pin of the chip when the third control pin of the chip is at a low level, the third input pin of the chip is disconnected from the third output pin of the chip when the third control pin of the chip is at a high level, the fourth input pin of the chip is connected to the fourth output pin of the chip when the fourth control pin of the chip is at a low level, and the fourth input pin of the chip is disconnected from the fourth output pin of the chip when the fourth control pin of the chip is at high level.

4. The motherboard of claim 3, wherein the power module comprises a first electronic switch and a second electronic switch, a first terminal of the first electronic switch is connected to the second pin of the second connector, a second terminal of the first electronic switch is connected to the first power input terminal, a third terminal of the first electronic switch is connected to the first pin of the first connector, a first terminal of the second electronic switch is connected to the output terminal of the inverter, a second terminal of the second electronic switch is connected to a second power input terminal, a third terminal of the second electronic switch is connected to the first pin of the first connector, the first and second electronic switches are turned on when the first terminals are at a low level, and the first and second electronic switches are turned off when the first terminals are at a high level.

5. The motherboard of claim 4, wherein the first and second electronic switches are p-channel field effect transistors.

6. The motherboard of claim 2, wherein the inverter is a single trigger Schmitt inverter.
